(19) United States
(12) Patent Application Publication
(10) Pub. No.: US 2016/0118555 A1
(43) Pub. Date: Apr. 28, 2016

(54) COMPOSITIONS OF RESIN-LINEAR ORGANOSILOXANE BLOCK COPOLYMERS

(71) Applicants: DOW CORNING CORPORATION, Midland, MI (US); DOW CORNING TORAY CO., LTD., Chiyoda-ku, Tokyo (JP)

(72) Inventors: Steven Swier, Midland, MI (US); Tadashi Okawa, Chiba Prefecture (JP); Kazuhiko Kojima, Chiba (JP)

(21) Appl. No.: 14/891,098

(22) PCT Filed: May 15, 2014
(86) PCT No.: PCT/US2014/038160

§ 371 Date: Nov. 13, 2015

Related U.S. Application Data
(60) Provisional application No. 61/823,495, filed on May 15, 2013.

(51) Int. Cl. H01L 33/56; C09D 183/10

(52) U.S. Cl. CPC H01L 33/56; C09D 183/10; C08K 2003/2241

(57) ABSTRACT

Curable compositions of “resin-linear” organosiloxane block copolymers comprising a nanoparticulate filler are disclosed. In some instances, even at high loading levels, curable and solid compositions comprising “resin linear” organosiloxane block copolymers and a nanoparticulate filler exhibit melt flow and cure behavior. In addition, the nanoparticulate filler present in the curable and solid compositions comprising “resin linear” organosiloxane block copolymers have the effect of significantly in creasing the refractive index of the curable and solid compositions.

### CROSS-REFERENCE TO RELATED APPLICATIONS

This application claims the benefit of U.S. Provisional Appl. Ser. No. 61/823,495, filed May 15, 2013, the entire of disclosure of which is incorporated by reference as if fully set forth herein.

### BACKGROUND

Light emitting diodes (LEDs) and solar panels use an encapsulant coating to protect electronic components from environmental factors. Such protective coatings must be optically clear to ensure maximum efficiency of these devices. Furthermore, these protective coatings must be tough, durable, long lasting, and yet easy to apply. Many of the currently available coatings, however, lack toughness; are not durable; are not long-lasting; and/or are not easy to apply. There is therefore a continuing need to identify protective and/or functional coatings in many areas of emerging technologies.

### SUMMARY

Embodiment 1 relates to a curable composition comprising:

i) an organosiloxane block copolymer comprising:
40 to 90 mole percent disiloxy units of the formula [R¹₂SiO_{2/2}],
10 to 60 mole percent trisiloxy units of the formula [R²SiO_{3/2}], 0.5 to 35 mole percent silanol groups [≡SiOH];

wherein:
each R¹, at each occurrence, is independently a C₁ to C₃₀ hydrocarbyl,
each R², at each occurrence, is independently a C₁ to C₂₀ hydrocarbyl;

wherein:
the disiloxy units [R¹₂SiO_{2/2}] are arranged in linear blocks having an average of from 10 to 400 disiloxy units [R¹₂SiO_{2/2}] per linear block,
the trisiloxy units [R²SiO_{3/2}] are arranged in non-linear blocks having a molecular weight of at least 500 g/mole, and at least 30% of the non-linear blocks are crosslinked with each other, each linear block is linked to at least one non-linear block; and
the organosiloxane block copolymer has a weight average molecular weight (M_{w}) of at least 20,000 g/mole; and

ii) a nanoparticulate filler.

Embodiment 2 relates to the curable composition of Embodiment 1, wherein the composition exhibits melt flow behavior.

Embodiment 3 relates to the curable composition of Embodiment 1, wherein the composition exhibits melt flow behavior at a nanoparticulate filler content of up to about 50 wt. %.

Embodiment 4 relates to the curable composition of Embodiment 1, further comprising a solvent and/or a phosphor.

Embodiment 5 relates to the curable composition of Embodiment 4, wherein the solvent is a polar solvent.

Embodiment 6 relates to the curable composition of Embodiment 5, wherein the polar solvent comprises tetrahydrofuran.

Embodiment 7 relates to the curable composition of Embodiment 1, wherein the nanoparticulate filler is present in an amount of from about 1% to about 60% based on the total weight of the composition.

Embodiment 8 relates to the curable composition of Embodiments 1-7, wherein R² is phenyl.

Embodiment 9 relates to the curable composition of Embodiments 1-8, wherein R² is naphthyl.

Embodiment 10 relates to the curable composition of

Embodiments 1-9, wherein R¹ is methyl or phenyl.

Embodiment 11 relates to the curable composition of Embodiments 1-10, wherein the disiloxy units have the formula [(CH₃)(C₆H₅)SiO_{2/2}].

Embodiment 12 relates to the curable composition of Embodiments 1-11, wherein the disiloxy units have the formula [(CH₃)₂SiO_{2/2}].

Embodiment 13 relates to a solid film composition comprising the curable composition of Embodiments 1-12.

Embodiment 14 relates to the solid film composition of Embodiment 13, wherein the solid composition has an optical transmittance of at least 95%.

Embodiment 15 relates to the solid film composition of Embodiment 13, wherein the solid composition has an ultra-high refractive index.

Embodiment 16 relates to the cured product of the composition of Embodiments 1-15.

Embodiment 17 relates to the cured product of Embodiment 16, wherein the cured product has an ultra-high refractive index.

Embodiment 18 relates to the cured product of Embodiment 16 or Embodiment 17, wherein the cured product is flexible.

Embodiment 19 relates to the cured product of Embodiment 18, wherein the cured product comprises less than 50 vol. % nanoparticulate filler.

Embodiment 20 relates to an LED encapsulant comprising the compositions of Embodiments 1-19.

### DESCRIPTION OF THE DRAWINGS

The drawings illustrate generally, by way of example, but not by way of limitation, various embodiments discussed in the present disclosure.

FIGS. 1 and 2 are photographs show the appearance of Sample 1 and Sample 5 films, respectively, described in Example 2.

FIG. 3 is a plot of vol % Alu C vs. thermal conductivity (W/m/K) and shows that, at least for the vol % Alu C range tested, the thermal conductivity was linear with regard to the vol % Alu C.

### DESCRIPTION OF THE EMBODIMENT

The present disclosure provides curable and solid compositions comprising “resin linear” organosiloxane block copolymers, where the compositions comprise nanoparticles and, in some embodiments, other components, including fillers and/or phosphors. The inclusion of nanoparticles into the curable and solid compositions is beneficial, in many instances, because the nanoparticles can influence certain functionality or alter the physical properties of a coating comprising the “resin linear” organsiloxane block copolymers described herein. “Resin linear” organosiloxane block copolymers are particularly suited to the incorporation of nanoparticles, even at relatively high levels (e.g., wt. %), because the nanoparticles do not appear to significantly affect the melt flow and cure behavior of the curable and solid compositions comprising “resin linear” organosiloxane block copolymers. In contrast, liquid dispense materials containing high levels of nanoparticles become too viscous to be practical. Also, “resin linear” organosiloxane block copolymers allow for the incorporation of certain types of nanoparticles (e.g., Al₂O₃) that would not be tolerated by other materials, without adverse effects when the materials are exposed to high temperatures. In some instances, the incorporation of nanoparticles into curable and solid compositions comprising “resin linear” organosiloxane block copolymers has additional beneficial effects, including, in some instances, significantly increasing the refractive index of the curable and solid composition. In other instances, the incorporation of nanoparticles can improve the barrier properties and/or enhance the thermal conductivity.

The compositions of the embodiments described herein comprise:

i) an organosiloxane block copolymer comprising:
40 to 90 mole percent disiloxy units of the formula [R¹₂SiO_{2/2}],
10 to 60 mole percent trisiloxy units of the formula [R²SiO_{3/2}],
0.5 to 35 mole percent silanol groups [≡SiOH];

wherein:

each R¹, at each occurrence, is independently a C₁ to C₃₀ hydrocarbyl,

each R², at each occurrence, is independently a C₁ to C₂₀ hydrocarbyl,

wherein:
the disiloxy units [R¹₂SiO_{2/2}] are arranged in linear blocks having an average of from 10 to 400 disiloxy units [R¹₂SiO_{2/2}] per linear block,
the trisiloxy units [R₂SiO_{3/2}] are arranged in non-linear blocks having a molecular weight of at least 500 g/mole, and at least 30% of the non-linear blocks are crosslinked with each other, each linear block is linked to at least one non-linear block, and
the organosiloxane block copolymer has an average molecular weight (M_{w}) of at least 20,000 g/mole; and

ii) nanoparticles.

### i) Organosiloxane Block Copolymer

The organosiloxane block copolymers comprise:
40 to 90 mole percent disiloxy units of the formula [R¹₂SiO_{2/2}],
10 to 60 mole percent trisiloxy units of the formula [R²SiO_{3/2}],
0.5 to 35 mole percent silanol groups [≡SiOH];

wherein:
each R¹, at each occurrence, is independently a C₁ to C₃₀ hydrocarbyl,
each R², at each occurrence, is independently a C₁ to C₂₀ hydrocarbyl;

wherein:
the disiloxy units [R¹₂SiO_{2/2}] are arranged in linear blocks having an average of from 10 to 400 disiloxy units [R¹₂SiO_{2/2}] per linear block,
the trisiloxy units [R²SiO_{3/2}] are arranged in non-linear blocks having a molecular weight of at least 500 g/mole, and at least 30% of the non-linear blocks are crosslinked with each other, each linear block is linked to at least one non-linear block; and
the organosiloxane block copolymer has a molecular weight of at least 20,000 g/mole.

The organopolysiloxanes of the embodiments described herein as “resin-linear” organosiloxane block copolymers. Methods of preparing such resin-linear organosiloxane block copolymers and compositions comprising such block copolymers are known in the art. See, e.g., Published PCT Application Nos. WO2012/040305 and WO2012/040367, the entireties of both of which are incorporated by reference as if fully set forth herein. Organopolysiloxanes are polymers containing siloxy units independently selected from [R₃SiO_{1/2}], [R₂SiO_{2/2}], [RSiO_{3/2}], or [SiO_{4/2}] siloxy units, where R may be, e.g., any organic group. These siloxy units are commonly referred to as M, D, T, and Q units respectively. These siloxy units can be combined in various manners to form cyclic, linear, or branched structures. The chemical and physical properties of the resulting polymeric structures vary depending on the number and type of siloxy units in the organopolysiloxane. For example, “linear” organopolysiloxanes contain, in some embodiments, mostly D, or [R₂SiO_{2/2}] siloxy units, which results in polydiorganosiloxanes that are fluids of varying viscosities, depending on the “degree of polymerization” or “dp” as indicated by the number of D units in the polydiorganosiloxane. “Linear” organopolysiloxanes, in some embodiments, have glass transition temperatures (T_{g}) that are lower than 25° C. “Resin” organopolysiloxanes result when a majority of the siloxy units are selected from T or Q siloxy units. When T siloxy units are predominately used to prepare an organopolysiloxane, the resulting organosiloxane is often referred to as a “resin” or a “silsesquioxane resin.” Increasing the amount of T or Q siloxy units in an organopolysiloxane, in some embodiments, results in polymers having increasing hardness and/or glass like properties. “Resin” organopolysiloxanes thus have higher T_{g} values, for example siloxane resins often have T_{g} values greater than 40° C., e.g., greater than 50° C., greater than 60° C., greater than 70° C., greater than 80° C., greater than 90° C. or greater than 100° C. In some embodiments, T_{g} for siloxane resins is from about 60° C. to about 100° C., e.g., from about 60° C. to about 80° C., from about 50° C. to about 100° C., from about 50° C. to about 80° C. or from about 70° C. to about 100° C.

As used herein “organosiloxane block copolymers” or “resin-linear organosiloxane block copolymers” refer to organopolysiloxanes containing “linear” D siloxy units in combination with “resin” T siloxy units. In some embodiments, the organosiloxane copolymers are “block” copolymers, as opposed to “random” copolymers. As such, the “resin-linear organosiloxane block copolymers” of the disclosed embodiments refer to organopolysiloxanes containing D and T siloxy units, where the D units (i.e., [R¹₂SiO_{2/2}] units) are primarily bonded together to form polymeric chains having, in some embodiments, an average of from 10 to 400 D units (e.g., an average of from about 10 to about 350 D units; about 10 to about 300 D units; about 10 to about 200 D units; about 10 to about 100 D units; about 50 to about 400 D units; about 100 to about 400 D units; about 150 to about 400 D units; about 200 to about 400 D units; about 300 to about 400 D units; about 50 to about 300 D units; about 100 to about 300 D units; about 150 to about 300 D units; about 200 to about 300 D units; about 100 to about 150 D units, about 115 to about 125 D units, about 90 to about 170 D units or about 110 to about 140 D units), which are referred herein as “linear blocks.”

The T units (i.e., [R²SiO_{3/2}]) are, in some embodiments, primarily bonded to each other to form branched polymeric chains, which are referred to as “non-linear blocks.” In some embodiments, a significant number of these non-linear blocks may further aggregate to form “nano-domains” when solid forms of the block copolymer are provided. In some embodiments, these nano-domains form a phase separate from a phase formed from linear blocks having D units, such that a resin-rich phase forms. In some embodiments, the disiloxy units [R¹₂SiO_{2/2}] are arranged in linear blocks having an average of from 10 to 400 disiloxy units [R¹₂SiO_{2/2}] per linear block (e.g., an average of from about 10 to about 350 D units; about 10 to about 300 D units; about 10 to about 200 D units; about 10 to about 100 D units; about 50 to about 400 D units; about 100 to about 400 D units; about 150 to about 400 D units; about 200 to about 400 D units; about 300 to about 400 D units; about 50 to about 300 D units; about 100 to about 300 D units; about 150 to about 300 D units; about 200 to about 300 D units; about 100 to about 150 D units, about 115 to about 125 D units, about 90 to about 170 D units or about 110 to about 140 D units), and the trisiloxy units [R²SiO_{3/2}] are arranged in non-linear blocks having a molecular weight of at least 500 g/mole and at least 30% of the non-linear blocks are crosslinked with each other.

In some embodiments, the non-linear blocks have a number average molecular weight of at least 500 g/mole, e.g., at least 1000 g/mole, at least 2000 g/mole, at least 3000 g/mole or at least 4000 g/mole; or have a molecular weight of from about 500 g/mole to about 4000 g/mole, from about 500 g/mole to about 3000 g/mole, from about 500 g/mole to about 2000 g/mole, from about 500 g/mole to about 1000 g/mole, from about 1000 g/mole to 2000 g/mole, from about 1000 g/mole to about 1500 g/mole, from about 1000 g/mole to about 1200 g/mole, from about 1000 g/mole to 3000 g/mole, from about 1000 g/mole to about 2500 g/mole, from about 1000 g/mole to about 4000 g/mole, from about 2000 g/mole to about 3000 g/mole or from about 2000 g/mole to about 4000 g/mole.

In some embodiments, at least 30% of the non-linear blocks are crosslinked with each other, e.g., at least 40% of the non-linear blocks are crosslinked with each other; at least 50% of the non-linear blocks are crosslinked with each other; at least 60% of the non-linear blocks are crosslinked with each other; at least 70% of the non-linear blocks are crosslinked with each other; or at least 80% of the non-linear blocks are crosslinked with each other, wherein all of the percentages given herein to indicate percent non-linear blocks that are crosslinked are in weight percent. In other embodiments, from about 30% to about 80% of the non-linear blocks are crosslinked with each other; from about 30% to about 70% of the non-linear blocks are crosslinked with each other; from about 30% to about 60% of the non-linear blocks are crosslinked with each other; from about 30% to about 50% of the non-linear blocks are crosslinked with each other; from about 30% to about 40% of the non-linear blocks are crosslinked with each other; from about 40% to about 80% of the non-linear blocks are crosslinked with each other; from about 40% to about 70% of the non-linear blocks are crosslinked with each other; from about 40% to about 60% of the non-linear blocks are crosslinked with each other; from about 40% to about 50% of the non-linear blocks are crosslinked with each other; from about 50% to about 80% of the non-linear blocks are crosslinked with each other; from about 50% to about 70% of the non-linear blocks are crosslinked with each other; from about 55% to about 70% of the non-linear blocks are crosslinked with each other, from about 50% to about 60% of the non-linear blocks are crosslinked with each other; from about 60% to about 80% of the non-linear blocks are crosslinked with each other; or from about 60% to about 70% of the non-linear blocks are crosslinked with each other.

The organosiloxane block copolymers (e.g., those comprising 40 to 90 mole percent disiloxy units of the formula [R¹₂SiO_{2/2}] and 10 to 60 mole percent trisiloxy units of the formula [R²SiO_{3/2}]) may be represented by the formula [R¹₂SiO_{2/2}]ₐ[R²SiO_{3/2}]_{b} where the subscripts a and b represent the mole fractions of the siloxy units in the copolymer,
a is about 0.4 to about 0.9,
   alternatively about 0.5 to about 0.9,
   alternatively about 0.6 to about 0.9,
b is about 0.1 to 0.6 about,
   alternatively about 0.1 to about 0.5,
   alternatively about 0.1 to about 0.4,

wherein each R¹, at each occurrence, is independently a C₁ to C₃₀ hydrocarbyl, and

each R², at each occurrence, is independently a C₁ to C₁₀ hydrocarbyl.

In some embodiments, the organosiloxane block copolymers of the embodiments described herein comprise 40 to 90 mole percent disiloxy units of the formula [R¹₂SiO_{2/2}], e.g., 50 to 90 mole percent disiloxy units of the formula [R¹₂SiO_{2/2}]; 60 to 90 mole percent disiloxy units of the formula [R¹₂SiO_{2/2}]; 65 to 90 mole percent disiloxy units of the formula [R¹₂SiO_{2/2}]; 70 to 90 mole percent disiloxy units of the formula [R¹₂SiO_{2/2}]; or 80 to 90 mole percent disiloxy units of the formula [R¹₂SiO_{2/2}]; 40 to 80 mole percent disiloxy units of the formula [R¹₂SiO_{2/2}]; 40 to 70 mole percent disiloxy units of the formula [R¹₂SiO_{2/2}]; 40 to 60 mole percent disiloxy units of the formula [R¹₂SiO_{2/2}]; 40 to 50 mole percent disiloxy units of the formula [R¹₂SiO_{2/2}]; 50 to 80 mole percent disiloxy units of the formula [R¹₂SiO_{2/2}]; 50 to 70 mole percent disiloxy units of the formula [R¹₂SiO_{2/2}]; 50 to 60 mole percent disiloxy units of the formula [R¹₂SiO_{2/2}]; 60 to 80 mole percent disiloxy units of the formula [R¹₂SiO_{2/2}]; 60 to 70 mole percent disiloxy units of the formula [R¹₂SiO_{2/2}]; or 70 to 80 mole percent disiloxy units of the formula [R¹₂SiO_{2/2}].

In some embodiments, the organosiloxane block copolymers of the embodiments described herein comprise 10 to 60 mole percent trisiloxy units of the formula [R²SiO_{3/2}], e.g., 10 to 20 mole percent trisiloxy units of the formula [R²SiO_{3/2}]; 10 to 30 mole percent trisiloxy units of the formula [R²SiO_{3/2}]; 10 to 35 mole percent trisiloxy units of the formula [R²SiO_{3/2}]; 10 to 40 mole percent trisiloxy units of the formula [R²SiO_{3/2}]; 10 to 50 mole percent trisiloxy units of the formula [R²SiO_{3/2}]; 20 to 30 mole percent trisiloxy units of the formula [R²SiO_{3/2}]; 20 to 35 mole percent trisiloxy units of the formula [R²SiO_{3/2}]; 20 to 40 mole percent trisiloxy units of the formula [R²SiO_{3/2}]; 20 to 50 mole percent trisiloxy units of the formula [R²SiO_{3/2}]; 20 to 60 mole percent trisiloxy units of the formula [R²SiO_{3/2}]; 30 to 40 mole percent trisiloxy units of the formula [R²SiO_{3/2}]; 30 to 50 mole percent trisiloxy units of the formula [R²SiO_{3/2}]; 30 to 60 mole percent trisiloxy units of the formula [R²SiO_{3/2}]; 40 to 50 mole percent trisiloxy units of the formula [R²SiO_{3/2}]; or 40 to 60 mole percent trisiloxy units of the formula [R²SiO_{3/2}].

It should be understood that the organosiloxane block copolymers of the embodiments described herein may contain additional siloxy units, such as M siloxy units, Q siloxy units, other unique D or T siloxy units (for example, having organic groups other than R¹ or R²), provided that the organosiloxane block copolymer contains the mole fractions of the disiloxy and trisiloxy units as described herein. In other words, the sum of the mole fractions as designated by subscripts a and b, do not necessarily have to sum to one. The sum of a+b may be less than one to account for minor amounts of other siloxy units that may be present in the organosiloxane block copolymer. Alternatively, the sum of a+b is greater than 0.6, alternatively greater than 0.7, alternatively greater than 0.8, or alternatively greater than 0.9. In some embodiments, the sum of a+b is from about 0.6 to about 0.9, e.g., from about 0.6 to about 0.8, from about 0.6 to about 0.7, from about 0.7 to about 0.9, from about 0.7 to about 0.8, or from about 0.8 to about 0.9.

In one embodiment, the organosiloxane block copolymer consists essentially of the disiloxy units of the formula [R¹₂SiO_{2/2}] and trisiloxy units of the formula [R²SiO_{3/2}], while also containing 0.5 to 25 mole percent silanol groups [≡SiOH] (e.g., 0.5 to 5 mole percent, 0.5 to 10 mole percent, 0.5 to 15 mole percent, 0.5 to 20 mole percent, 5 to 10 mole percent, 5 to 15 mole percent, 5 to 20 mole percent, 5 to 25 mole percent, 10 to 15 mole percent 10 to 20 mole percent, 10 to 25 mole percent, 15 to 20 mole percent, 15 to 25 mole percent, or 20 to 25 mole percent), where R¹ and R² are as defined above. Thus, some embodiments, the sum of a+b (when using mole fractions to represent the amount of disiloxy and trisiloxy units in the copolymer) is greater than 0.95, alternatively greater than 0.98.

In some embodiments, the resin-linear organosiloxane block copolymers also contain silanol groups (≡SiOH). The amount of silanol groups present on the organosiloxane block copolymer may vary from 0.5 to 35 mole percent silanol groups [≡SiOH],

alternatively from 2 to 32 mole percent silanol groups [≡SiOH],

alternatively from 8 to 22 mole percent silanol groups [≡SiOH].

The silanol groups may be present on any siloxy units within the organosiloxane block copolymer. The amount described herein represent the total amount of silanol groups found in the organosiloxane block copolymer. In some embodiments, the majority (e.g., greater than 75%, greater than 80%, greater than 90%; from about 75% to about 90%, from about 80% to about 90%, or from about 75% to about 85%) of the silanol groups will reside on the trisiloxy units, i.e., the resin component of the block copolymer. Although not wishing to be bound by any theory, the silanol groups present on the resin component of the organosiloxane block copolymer allows for the block copolymer to further react or cure at elevated temperatures.

At each occurrence, each R¹ in the above disiloxy unit is independently a C₁ to C₃₀ hydrocarbyl, where the hydrocarbyl group may independently be an alkyl, aryl, or alkylaryl group. Each R¹, at each occurrence, may independently be a C₁ to C₃₀ alkyl group, alternatively, at each occurrence, each R¹ may be a C₁ to C₁₈ alkyl group. Alternatively each R¹, at each occurrence, may be a C₁ to C₆ alkyl group such as methyl, ethyl, propyl, butyl, pentyl, or hexyl. Alternatively each R¹, at each occurrence, may be methyl. Each R¹, at each occurrence, may be an aryl group, such as phenyl, naphthyl, or an anthryl group. Alternatively, each R¹, at each occurrence, may be any combination of the aforementioned alkyl or aryl groups such that, in some embodiments, each disiloxy unit may have two alkyl groups (e.g., two methyl groups); two aryl groups (e.g., two phenyl groups); or an alkyl (e.g., methyl) and an aryl group (e.g., phenyl). Alternatively, each R¹, at each occurrence, is phenyl or methyl.

Each R², at each occurrence, in the above trisiloxy unit is independently a C₁ to C₂₀ hydrocarbyl, where the hydrocarbyl group may independently be an alkyl, aryl, or alkylaryl group. Each R², at each occurrence, may be a C₁ to C₂₀ alkyl group, alternatively each R², at each occurrence, may be a C₁ to C₁₈ alkyl group. Alternatively each R², at each occurrence, may be a C₁ to C₆ alkyl group such as methyl, ethyl, propyl, butyl, pentyl, or hexyl. Alternatively each R², at each occurrence, may be methyl. Each R², at each occurrence, may be an aryl group, such as phenyl, naphthyl, or an anthryl group. Alternatively, each R², at each occurrence, may be any combination of the aforementioned alkyl or aryl groups such that, in some embodiments, each disiloxy unit may have two alkyl groups (e.g., two methyl groups); two aryl groups (e.g., two phenyl groups); or an alkyl (e.g., methyl) and an aryl group (e.g., phenyl). Alternatively, each R², at each occurrence, is phenyl or methyl.

As used throughout the specification, hydrocarbyl also includes substituted hydrocarbyls. “Substituted” as used throughout the specification refers broadly to replacement of one or more of the hydrogen atoms of the group with substituents known to those skilled in the art and resulting in a stable compound as described herein. Examples of suitable substituents include, but are not limited to, alkyl, alkenyl, alkynyl, cycloalkyl, aryl, alkaryl, hydroxy, alkoxy, aryloxy, carboxy (i.e., CO₂H), carboxyalkyl, carboxyaryl, cyano, nitro and the like. Substituted hydrocabyl also includes halogen substituted hydrocarbyls, where the halogen may be fluorine, chlorine, bromine or combinations thereof

In some embodiments, fluorinated organosiloxane block copolymers are also contemplated herein. Such fluorinated orangsiloxane block copolymers are described in U.S. Provisional Patent Appl. Ser. No. 61/608,732, filed Mar. 9, 2012; and PCT Appl. No. PCT/US2013/027904, filed Feb. 27, 2013, the entire disclosures of both of which are incorporated by reference as if fully set forth herein.

The formula [R¹₂SiO_{2/2}]ₐ[R²SiO_{3/2}]_{b}, and related formulae using mole fractions, as used herein to describe the organosiloxane block copolymers, does not indicate structural ordering of the disiloxy [R¹₂SiO_{2/2}] and trisiloxy [R²SiO_{3/2}] units in the copolymer. Rather, this formula is meant to provide a convenient notation to describe the relative amounts of the two units in the copolymer, as per the mole fractions described herein via the subscripts a and b. The mole fractions of the various siloxy units in the present organosiloxane block copolymers, as well as the silanol content, may be readily determined by ²⁹Si NMR techniques, as detailed in the Examples.

The organosiloxane block copolymers of the embodiments described herein have a weight average molecular weight (M_{w}) of at least 20,000 g/mole, alternatively a weight average molecular weight of at least 40,000 g/mole, alternatively a weight average molecular weight of at least 50,000 g/mole, alternatively a weight average molecular weight of at least 60,000 g/mole, alternatively a weight average molecular weight of at least 70,000 g/mole, or alternatively a weight average molecular weight of at least 80,000 g/mole. In some embodiments, the organosiloxane block copolymers of the embodiments described herein have a weight average molecular weight (M_{w}) of from about 20,000 g/mole to about 250,000 g/mole or from about 100,000 g/mole to about 250,000 g/mole, alternatively a weight average molecular weight of from about 40,000 g/mole to about 100,000 g/mole, alternatively a weight average molecular weight of from about 50,000 g/mole to about 100,000 g/mole, alternatively a weight average molecular weight of from about 50,000 g/mole to about 80,000 g/mole, alternatively a weight average molecular weight of from about 50,000 g/mole to about 70,000 g/mole, alternatively a weight average molecular weight of from about 50,000 g/mole to about 60,000 g/mole. In some embodiments, the organosiloxane block copolymers of the embodiments described herein have a number average molecular weight (Mₙ) of from about 15,000 to about 50,000 g/mole; from about 15,000 to about 30,000 g/mole; from about 20,000 to about 30,000 g/mole; or from about 20,000 to about 25,000 g/mole. The average molecular weight may be readily determined using Gel Permeation Chromatography (GPC) techniques, such as those described in the Examples.

In some embodiments, the structural ordering of the disiloxy and trisiloxy units may be further described as follows: the disiloxy units [R¹₂SiO_{2/2}] are arranged in linear blocks having an average of from 10 to 400 disiloxy units [R¹₂SiO_{2/2}] per linear block, and the trisiloxy units [R²SiO_{3/2}] are arranged in non-linear blocks having a molecular weight of at least 500 g/mole. Each linear block is linked to at least one non-linear block in the block copolymer. Furthermore, at least 30% of the non-linear blocks are crosslinked with each other,

alternatively at least at 40% of the non-linear blocks are crosslinked with each other,

alternatively at least at 50% of the non-linear blocks are crosslinked with each other.

In other embodiments, from about 30% to about 80% of the non-linear blocks are crosslinked with each other; from about 30% to about 70% of the non-linear blocks are crosslinked with each other; from about 30% to about 60% of the non-linear blocks are crosslinked with each other; from about 30% to about 50% of the non-linear blocks are crosslinked with each other; from about 30% to about 40% of the non-linear blocks are crosslinked with each other; from about 40% to about 80% of the non-linear blocks are crosslinked with each other; from about 40% to about 70% of the non-linear blocks are crosslinked with each other; from about 40% to about 60% of the non-linear blocks are crosslinked with each other; from about 40% to about 50% of the non-linear blocks are crosslinked with each other; from about 50% to about 80% of the non-linear blocks are crosslinked with each other; from about 50% to about 70% of the non-linear blocks are crosslinked with each other; from about 50% to about 60% of the non-linear blocks are crosslinked with each other; from about 60% to about 80% of the non-linear blocks are crosslinked with each other; or from about 60% to about 70% of the non-linear blocks are crosslinked with each other.

The crosslinking of the non-linear blocks may be accomplished via a variety of chemical mechanisms and/or moieties. For example, crosslinking of non-linear blocks within the block copolymer may result from the condensation of residual silanol groups present in the non-linear blocks of the copolymer. Crosslinking of the non-linear blocks within the block copolymer may also occur between “free resin” components and the non-linear blocks. “Free resin” components may be present in the block copolymer compositions as a result of using an excess amount of an organosiloxane resin during the preparation of the block copolymer. The free resin component may crosslink with the non-linear blocks by condensation of the residual silanol groups present on the non-blocks and on the free resin. The free resin may provide crosslinking by reacting with lower molecular weight compounds added as crosslinkers, as described herein. The free resin, when present, may be present in an amount of from about 10% to about 20% by weight of the organosiloxane block copolymers of the embodiments described herein, e.g., from about 15% to about 20% by weight organosiloxane block copolymers of the embodiments described herein.

Alternatively, certain compounds may be added during the preparation of the block copolymer to specifically crosslink the non-resin blocks. These crosslinking compounds may include an organosilane having the formula R⁵_{q}SiX_{4-q}, which is added during the formation of the block copolymer (step II) as discussed herein), where R⁵ is a C₁ to C₈ hydrocarbyl or a C₁ to C₈ halogen-substituted hydrocarbyl; X is a hydrolyzable group; and q is 0, 1, or 2. R⁵ is a C₁ to C₈ hydrocarbyl or a C₁ to C₈ halogen-substituted hydrocarbyl, or alternatively R⁵ is a C₁ to C₈ alkyl group, or alternatively a phenyl group, or alternatively R⁵ is methyl, ethyl, or a combination of methyl and ethyl. X is any hydrolyzable group, alternatively X may be an oximo, acetoxy, halogen atom, hydroxyl (OH), or an alkoxy group.

In one embodiment, the organosilane having the formula R⁵_{q}SiX_{4-q} is an alkyltriacetoxysilane, such as methyltriacetoxysilane, ethyltriacetoxysilane, or a combination of both. Commercially available representative alkyltriacetoxysilanes include ETS-900 (Dow Corning Corp., Midland, Mich.).

Other suitable, non-limiting organosilanes useful as crosslinkers include; methyl tris(methylethylketoxime)silane (MTO), methyl triacetoxysilane, ethyl triacetoxysilane, tetraacetoxysilane, tetraoximesilane, dimethyl diacetoxysilane, dimethyl dioximesilane, and methyl tris(methylmethylketoxime)silane.

In some embodiments, the crosslinks within the block copolymer will primarily be siloxane bonds, ≡Si—O—Si≡, resulting from the condensation of silanol groups, as discussed herein.

The amount of crosslinking in the block copolymer may be estimated by determining the average molecular weight of the block copolymer, such as with GPC techniques. In some embodiments, crosslinking the block copolymer increases its average molecular weight. Thus, an estimation of the extent of crosslinking may be made, given the average molecular weight of the block copolymer, the selection of the linear siloxy component (that is the chain length as indicated by its degree of polymerization), and the molecular weight of the non-linear block (which is primarily controlled by the selection of the selection of the organosiloxane resin used to prepare the block copolymer).

The present disclosure further provides curable compositions comprising:
a) the organosiloxane block copolymers as described herein, in some embodiments in combination with a stabilizer or a superbase (as described herein),
b) a nanoparticulate filler and optionally a phosphor; and
c) an organic solvent.
   See, e.g., PCT Appl. No. PCT/US2012/067334, filed Nov. 30, 2012; U.S. Provisional Appl. No. 61/566,031, filed Dec. 2, 2011; PCT Appl. No. PCT/US2012/069701, filed Dec. 14, 2012; and U.S. Provisional Appl. No. 61/570,477, filed Dec. 14, 2012, the entireties of all of which are incorporated by reference as if fully set forth herein. In some embodiments, the curable compositions, and solid compositions derived therefrom, comprise a phosphor.

In some embodiments, the organic solvent is an aromatic solvent, such as benzene, toluene, or xylene. In other embodiments, the organic solvent is a polar solvent. In some embodiments, the polar solvent disrupts or substantially disrupts any, a substantial amount or all hydrogen bonding between a nanoparticulate filler and moieties on the organosiloxane block copolymers (e.g., silanol groups) capable of hydrogen bonding with a nanoparticulate filler. Polar solvents include, but are not limited to, tetrahydrofuran and alkyl ethers and esters of ethylene glycol such as ethylene glycol monomethyl ether, ethylene glycol monoethyl ether, ethyelene glycol monopropyl ether, ethylene glycol monoisopropyl ether, ethylene glycol monobutyl ether, ethylene glycol monophenyl ether, ethylene glycol monobenzyl ether, diethylene glycol monomethyl ether, diethylene glycol monoethyl ether, diethylene glycol mono-n-butyl ether, ethylene glycol dimethyl ether, ethylene glycol diethyl ether, ethylene glycol dibutyl ether, ethylene glycol methyl ether acetate, ethylene glycol monoethyl ether acetate, ethylene glycol monobutyl ether acetate, and the like.

In one embodiment, the curable compositions may further contain an organosiloxane resin (e.g., free resin that is not part of the block copolymer). The organosiloxane resin present in these compositions is, in some embodiments, the same organosiloxane resin used to prepare the organosiloxane block copolymer. Thus, the organosiloxane resin may comprise at least 60 mole % of [R²SiO_{3/2}] siloxy units in its formula (e.g., at least 70 mole % of [R²SiO_{3/2}] siloxy units or at least 80 mole % of [R²SiO_{3/2}] siloxy units; or 60-70 mole % [R²SiO_{3/2}] siloxy units, 60-80 mole % [R²SiO_{3/2}] siloxy units or 70-80 mole % [R²SiO_{3/2}] siloxy units), wherein each R², at each occurrence, is independently a C₁ to C₂₀ hydrocarbyl. Alternatively, the organosiloxane resin is a silsesquioxane resin, or alternatively a phenyl silsesquioxane resin.

The amount of the organosiloxane block copolymers, organic solvent, and optional organosiloxane resin in the present curable composition may vary. A curable composition of the present disclosure may contain:
40 to 80 weight % of the organosiloxane block copolymer as described herein (e.g., 40 to 70 weight %, 40 to 60 weight %, 40 to 50 weight %); 10 to 80 weight % of the organic solvent (e.g., 10 to 70 weight %, 10 to 60 weight %, 10 to 50 weight %, 10 to 40 weight %, 10 to 30 weight %, 10 to 20 weight %, 20 to 80 weight %, 30 to 80 weight %, 40 to 80 weight %, 50 to 80 weight %, 60 to 80 weight %, or 70 to 80 weight); and
5 to 40 weight % of the organosiloxane resin (e.g., 5 to 30 weight %, 5 to 20 weight %, 5 to 10 weight %, 10 to 40 weight %, 10 to 30 weight %, 10 to 20 weight %, 20 to 40 weight % or 30 to 40 weight %);
   such that the sum of the weight % of these components does not exceed 100%. In one embodiment, the curable compositions consist essentially of the organosiloxane block copolymer as described herein, the organic solvent, and the organosiloxane resin. In some embodiments, the weight % of these components sum to 100%, or nearly 100%.

In yet another embodiment, the curable compositions contain a cure catalyst. The cure catalyst may be selected from any catalyst known in the art to effect condensation cure of organosiloxanes, such as various tin or titanium catalysts. Condensation catalyst can be any condensation catalyst that may be used to promote condensation of silicon bonded hydroxy (=silanol) groups to form Si—O—Si linkages. Examples include, but are not limited to, amines and complexes of lead, tin, titanium, zinc, and iron. Other examples include, but are not limited to basic compounds, such as trimethylbenzylammonium hydroxide, tetramethylammonium hydroxide, n-hexylamine, tributylamine, diazabicycloundecene (DBU) and dicyandiamide; and metal-containing compounds such as tetraisopropyl titanate, tetrabutyl titanate, titanium acetylacetonate, aluminum triisobutoxide, aluminum triisopropoxide, zirconium tetra(acetylacetonato), zirconium tetrabutylate, cobalt octylate, cobalt acetylacetonato, iron acetylacetonato, tin acetylacetonato, dibutyltin octylate, dibutyltin laurate, zinc octylate, zinc bezoate, zinc p-tert-butylbenzoate, zinc laurate, zinc stearate, aluminium phosphate, and alminium triisopropoxide; organic titanium chelates such as aluminium trisacetylacetonate, aluminium bisethylacetoacetate monoacetylacetonate, diisopropoxybis(ethylacetoacetate)titanium, and diisopropoxybis(ethylacetoacetate)titanium. In some embodiments, the condensation catalysts include zinc octylate, zinc bezoate, zinc p-tert-butylbenzoate, zinc laurate, zinc stearate, aluminium phosphate, and aluminum triisopropoxide. See, e.g., U.S. Pat. No. 8,193,269, the entire disclosure of which is incorporated by reference as if fully set forth herein. Other examples of condensation catalysts include, but are not limited to aluminum alkoxides, antimony alkoxides, barium alkoxides, boron alkoxides, calcium alkoxides, cerium alkoxides, erbium alkoxides, gallium alkoxides, silicon alkoxides, germanium alkoxides, hafnium alkoxides, indium alkoxides, iron alkoxides, lanthanum alkoxides, magnesium alkoxides, neodymium alkoxides, samarium alkoxides, strontium alkoxides, tantalum alkoxides, titanium alkoxides, tin alkoxides, vanadium alkoxide oxides, yttrium alkoxides, zinc alkoxides, zirconium alkoxides, titanium or zirconium compounds, especially titanium and zirconium alkoxides, and chelates and oligo- and polycondensates of the above alkoxides, dialkyltin diacetate, tin(II) octoate, dialkyltin diacylate, dialkyltin oxide and double metal alkoxides. Double metal alkoxides are alkoxides containing two different metals in a particular ratio. In some embodiments, the condensation catalysts include titanium tetraethylate, titanium tetrapropylate, titanium tetraisopropylate, titanium tetrabutylate, titanium tetraisooctylate, titanium isopropylate tristearoylate, titanium truisopropylate stearoylate, titanium diisopropylate distearoylate, zirconium tetrapropylate, zirconium tetraisopropylate, zirconium tetrabutylate. See, e.g., U.S. Pat. No. 7,005,460, the entire disclosure of which is incorporated by reference as if fully set forth herein. In addition, the condensation catalysts include titanates, zirconates and hafnates as described in DE 4427528 C2 and EP 0 639 622 B1, both of which are incorporated by reference as if fully set forth herein.

The organosiloxane block copolymers and curable compositions containing the organosiloxane block copolymer may be prepared by the methods as described further herein.

Solid compositions containing the resin-linear organosiloxane block copolymers, a nanoparticulate filler, and optionally a phosphor, may be prepared by removing the solvent from the curable organosiloxane block copolymer compositions as described herein. In some embodiments, the curable compositions, and solid compositions derived therefrom, comprise a phosphor. The solvent may be removed by any known processing techniques. In one embodiment, a film of the curable compositions containing the organosiloxane block copolymers is formed, and the solvent is allowed to evaporate from the film. Subjecting the films to elevated temperatures, and/or reduced pressures, will accelerate solvent removal and subsequent formation of the solid curable composition. Alternatively, the curable compositions may be passed through an extruder to remove solvent and provide the solid composition in the form of a ribbon or pellets. Coating operations against a release film could also be used as in slot die coating, knife over roll, rod, or gravure coating. Also, roll-to-roll coating operations could be used to prepare a solid film. In coating operations, a conveyer oven or other means of heating and evacuating the solution can be used to drive off the solvent and obtain the final solid film.

Although not wishing to be bound by any theory, it is believed that the structural ordering of the disiloxy and trisiloxy units in the organosiloxane block copolymer as described herein may provide the copolymer with certain unique physical property characteristics when solid compositions of the block copolymer are formed. For example, the structural ordering of the disiloxy and trisiloxy units in the copolymer may provide solid coatings that allow for a high optical transmittance of visible light (e.g., at wavelengths above 350 nm). The structural ordering may also allow the organosiloxane block copolymer to flow and cure upon heating, yet remain stable at room temperature. They may also be processed using lamination techniques. These properties are useful to provide coatings for various electronic articles to improve weather resistance and durability, while providing low cost and easy procedures that are energy efficient.

The present disclosure further relates to solid forms of the aforementioned organosiloxane block copolymers and solid compositions derived from the curable compositions described herein comprising the organosiloxane block copolymers.

In some embodiments, the aforementioned organosiloxane block copolymers are isolated in a solid form, for example by casting films of a solution of the block copolymer in an organic solvent (e.g., benzene, toluene, xylene or combinations thereof) and allowing the solvent to evaporate. Under these conditions, the aforementioned organosiloxane block copolymers can be provided as solutions in an organic solvent containing from about 50 wt % to about 80 wt % solids, e.g., from about 60 wt % to about 80 wt %, from about 70 wt % to about 80 wt % or from about 75 wt % to about 80 wt % solids. In some embodiments, the solvent is toluene. In some embodiments, such solutions will have a viscosity of from about 1500 cSt to about 4000 cSt at 25° C., e.g., from about 1500 cSt to about 3000 cSt, from about 2000 cSt to about 4000 cSt or from about 2000 cSt to about 3000 cSt at 25° C.

Upon drying or forming a solid, the non-linear blocks of the block copolymer further aggregate together to form “nano-domains.” As used herein, “predominately aggregated” means the majority of the non-linear blocks of the organosiloxane block copolymer are found in certain regions of the solid composition, described herein as “nano-domains.” As used herein, “nano-domains” refers to those phase regions within the solid block copolymer compositions that are phase separated within the solid block copolymer compositions and possess at least one dimension sized from 1 to 100 nanometers. The nano-domains may vary in shape, providing at least one dimension of the nano-domain is sized from 1 to 100 nanometers. Thus, the nano-domains may be regular or irregularly shaped. The nano-domains may be spherically shaped, tubular shaped, and in some instances lamellar shaped.

In a further embodiment, the solid organosiloxane block copolymers as described herein contain a first phase and an incompatible second phase, the first phase containing predominately the disiloxy units [R¹₂SiO_{2/2}] as defined above, the second phase containing predominately the trisiloxy units [R²SiO_{3/2}] as defined above, the non-linear blocks being sufficiently aggregated into nano-domains which are incompatible with the first phase.

When solid compositions are formed from the curable compositions of the organosiloxane block copolymer, which also contain an organosiloxane resin, as described herein, the organosiloxane resin also predominately aggregates within the nano-domains.

The structural ordering of the disiloxy and trisiloxy units in the solid block copolymers of the present disclosure, and characterization of the nano-domains, may be determined explicitly using certain analytical techniques such as Transmission Electron Microscopic (TEM) techniques, Atomic Force Microscopy (AFM), Small Angle Neutron Scattering, Small Angle X-Ray Scattering, and Scanning Electron Microscopy.

Alternatively, the structural ordering of the disiloxy and trisiloxy units in the block copolymer, and formation of nano-domains, may be implied by characterizing certain physical properties of coatings resulting from the present organosiloxane block copolymers. For example, the present organosiloxane copolymers may provide coatings that have an optical transmittance of visible light greater than 95%. One skilled in the art recognizes that such optical clarity is possible (other than refractive index matching of the two phases) only when visible light is able to pass through such a medium and not be diffracted by particles (or domains as used herein) having a size greater than 150 nanometers. As the particle size, or domains further decreases, the optical clarity may be further improved. Thus, coatings derived from the present organosiloxane copolymers may have an optical transmittance of visible light of at least 95%, e.g., at least 96%; at least 97%; at least 98%; at least 99%; or 100% transmittance of visible light. As used herein, the term “visible light” includes light with wavelengths above 350 nm.

One advantage of the present resin-linear organopolysiloxanes block copolymers is that they can be processed several times, because the processing temperature (T_{processing}) is less than the temperature required to finally cure (T_{cure}) the organosiloxane block copolymer, i.e., T_{processing}<T_{cure}. However the organosiloxane copolymer will cure and achieve high temperature stability when T_{processing} is taken above T_{cure}. Thus, the present resin-linear organopolysiloxanes block copolymers offer a significant advantage of being “re-processable” in conjunction with the benefits that may be associated with silicones, such as; hydrophobicity, high temperature stability, moisture/UV resistance.

In one embodiment, the solid compositions of the organosiloxane block copolymers may be considered as “melt processable.” In some embodiments, the solid compositions, such as a coating formed from a film of a solution containing the organosiloxane block copolymers, exhibit fluid behavior at elevated temperatures, that is upon “melting.” The “melt processable” features of the solid compositions of the organosiloxane block copolymers may be monitored by measuring the “melt flow temperature” of the solid compositions, that is when the solid composition demonstrates liquid behavior. The melt flow temperature may specifically be determined by measuring the storage modulus (G′), loss modulus (G″) and tan delta as a function of temperature storage using commercially available instruments. For example, a commercial rheometer (such as TA Instruments' ARES-RDA with 2KSTD standard flexular pivot spring transducer, with forced convection oven) may be used to measure the storage modulus (G′), loss modulus (G″) and tan delta as a function of temperature. Test specimens (e.g., 8 mm wide, 1 mm thick) may be loaded in between parallel plates and measured using small strain oscillatory rheology while ramping the temperature in a range from 25° C. to 300° C. at 2° C./min (frequency 1 Hz). The flow onset may be calculated as the inflection temperature in the G′ drop (labeled FLOW), the viscosity at 120° C. is reported as a measure for melt processability and the cure onset is calculated as the onset temperature in the G′ rise (labeled CURE). In some embodiments, the FLOW of the solid compositions will also correlate to the glass transition temperature of the non-linear segments (i.e., the resin component) in the organosiloxane block copolymer.

In some embodiments, the time to reach tan delta=1 from a value higher than 1 is from about 3 to about 60 minutes at 150° C., e.g., from about 3 to about 5 minutes at 150° C., from about 10 to about 15 minutes at 150° C., from about 10 to about 12 minutes at 150° C., from about 8 to about 10 minutes at 150° C. or from about 30 minutes to about 60 minutes at 150° C. In other embodiments, the tan delta=1 is from about 3 to about 60 seconds at 150° C., e.g., from about 3 to about 30 seconds at 150° C., from about 10 to about 45 seconds at 150° C., from about 5 to about 50 seconds at 150° C., from about 10 to about 30 seconds at 150° C. or from about 30 seconds to about 60 seconds at 150° C. In still other embodiments, the tan delta=1 is from about 5 to about 1200 seconds at 120° C., e.g., from about 20 to about 60 seconds at 120° C., from about 20 to about 600 seconds at 120° C., from about 60 to about 1200 seconds at 120° C., from about 5 to about 100 seconds at 120° C., from about 10 to about 60 seconds at 120° C. or from about 30 seconds to about 60 seconds at 120° C.

In a further embodiment, the solid compositions may be characterized as having a melt flow temperature ranging from 25° C. to 200° C., alternatively from 25° C. to 160° C., or alternatively from 50° C. to 160° C.

It is believed that the melt processability benefits enables the reflow of solid compositions of the organosiloxane block copolymers around device architectures at temperatures below T_{cure}, after an initial coating or solid is formed on the device. This feature is very beneficial to encapsulated various electronic devices.

In one embodiment, the solid compositions of the organosiloxane block copolymers may be considered as “curable.” In some embodiments, the solid compositions, such as a coating formed from a film of a solution containing the organosiloxane block copolymers, may undergo further physical property changes by further curing the block copolymer. As discussed herein, the present organosiloxane block copolymers contain a certain amount of silanol groups. It is believed that the presence of these silanol groups on the block copolymer permit further reactivity, i.e., a cure mechanism. Upon curing, the physical properties of solid compositions may be further altered, as discussed in certain embodiments below.

Alternatively, the “melt processability” and/or cure of the solid compositions of the organosiloxane block copolymers may be determined by rheological measurements at various temperatures.

The solid compositions containing the organosiloxane block copolymers may have a storage modulus (G′) at 25° C. ranging from 0.01 MPa to 500 MPa and a loss modulus (G″) ranging from 0.001 MPa to 250 MPa, alternatively a storage modulus (G′) at 25° C. ranging from 0.1 MPa to 250 MPa and a loss modulus (G″) ranging from 0.01 MPa to 125 MPa, alternatively a storage modulus (G′) at 25° C. ranging from 0.1 MPa to 200 MPa and a loss modulus (G″) ranging from 0.01 MPa to 100 MPa.

The solid compositions containing the organosiloxane block copolymers may have a storage modulus (G′) at 120° C. ranging from 10 Pa to 500,000 Pa and a loss modulus (G″) ranging from 10 Pa to 500,000 Pa, alternatively a storage modulus (G′) at 120° C. ranging from 20 Pa to 250,000 Pa and a loss modulus (G″) ranging from 20 Pa to 250,000 Pa, alternatively a storage modulus (G′) at 120° C. ranging from 30 Pa to 200,000 Pa and a loss modulus (G″) ranging from 30 Pa to 200,000 Pa.

The solid compositions containing the organosiloxane block copolymers may have a storage modulus (G′) at 200° C. ranging from 10 Pa to 100,000 Pa and a loss modulus (G″) ranging from 5 Pa to 80,000 Pa, alternatively a storage modulus (G′) at 200° C. ranging from 20 Pa to 75,000 Pa and a loss modulus (G″) ranging from 10 Pa to 65,000 Pa, alternatively a storage modulus (G′) at 200° C. ranging from 30 Pa to 50,000 Pa and a loss modulus (G″) ranging from 15 Pa to 40,000 Pa.

In some embodiments, the solid curable compositions of the embodiments included herein may be also be characterized by determining the G′/G″ cross-over temperature. This “crossover” temperature indicates the onset of condensation cure for the resin-linear copolymer. The G′/G″ cross-over temperatures may vary with metal ligand complex concentration and may be related to the reduction in mobility of the resin-rich phase, where silanol groups may be present only on the resin and, around 100° C., the temperature is very close to the T_{g} of the resin phase. This will result in significant mobility reduction. Thus, in certain embodiments, curable compositions may have a viscosity of at least 1700 Pa·s at 120° C., alternatively at least 2000 Pa·s at 120° C., alternatively at least 5000 Pa·s at 120° C., alternatively at least 10,000 Pa·s at 120° C., alternatively at least 20,000 Pa·s at 120° C. or alternatively at least 30,000 Pa·s at 120° C. In other embodiments, the curable compositions may have a viscosity of from about 1500 Pa·s at 120° C. to about 50,000 Pa·s at 120° C.; e.g., from about 1700 Pa·s at 120° C. to about 3000 Pa·s at 120° C.; about 2500 Pa·s at 120° C. to about 5000 Pa·s at 120° C.; from about 1500 Pa·s at 120° C. to about 2000 Pa·s at 120° C.; from about 1600 Pa·s at 120° C. to about 1800 Pa·s at 120° C., from about 10,000 Pa·s at 120° C. to about 40,000 Pa·s at 120° C., from about 20,000 Pa·s at 120° C. to about 40,000 Pa·s at 120° C. or from about 25,000 Pa·s at 120° C. to about 35,000 Pa·s at 120° C.

The solid compositions may be further characterized by certain physical properties such as tensile strength and % elongation at break. The present solid compositions derived from the aforementioned organosiloxane block copolymers may have an initial tensile strength greater than 1.0 MPa, alternatively greater than 1.5 MPa, or alternatively greater than 2 MPa. In some embodiments, the solid compositions may have an initial tensile strength for from 1.0 MPa to about 10 MPa, e.g., from about 1.5 MPa to about 10 MPa, from about 2 MPa to about 10 MPa, from about 5 MPa to about 10 MPa or from about 7 MPa to about 10 MPa. The present solid compositions derived from the aforementioned organosiloxane block copolymers may have an initial % elongation at break (or rupture) greater than 40%, alternatively greater than 50%, or alternatively greater than 75%. In some embodiments, the solid compositions may have a % elongation at break (or rupture) of from about 20% to about 90%, e.g., from about 25% to about 50%, from about 20% to about 60%, from about 40% to about 60%, from about 40% to about 50%, or from about 75% to about 90%. As used herein, tensile strength and % elongation at break are measured according to ASTM D412.

### ii) Nanoparticulate Filler

The compositions of the present disclosure may contain nanoparticles. The term “nanoparticles” and “nanoparticulate filler” are used interchangeably herein. As used herein, the term “nanoparticles” refers broadly to particles (primary particles or associated primary particles) having a largest dimension or average largest dimension of less than about 100 nm. In some embodiments, the nanoparticles may have a largest dimension or average largest dimension less than about 50 nm, less than about 20 nm, less than about 10 nm, or less than about 5 nm. Furthermore, the largest dimension or average largest dimension of the nanoparticles may be between about 1 to about 50 nm, between about 2 to about 50 nm, or between about 2 to about 20 nm.

The nanoparticles may be added in an amount ranging from about 0.1% to about 95%, e.g., from about 2% to about 90%, from about 1% to about 60%; from about 25% to about 60%; from about 30% to about 60%; from about 40% to about 60%; from about 50 to about 60%; from about 25% to about 50%; from about 25% to about 40%; from about 25% to about 30%; from about 30% to about 40%; from about 30% to about 50%; or from about 40% to about 50%; based on the total weight of the composition.

The nanoparticles may be present in compositions of the present disclosure in an amount ranging from about 2 to about 50 vol. %, e.g., from about 2 to about 30 vol. %, from about 5 to about 20 vol. %, from about 10 to about 20 vol. % or from about 12 to about 17 vol. %. In some embodiments, compositions of the present disclosure (e.g., cured compositions/products) contain less than 50 vol. % nanoparticulate filler, e.g., less than 40 vol. %, less than 30 vol. %, less than 20 vol. % or less than 10 vol. %.

Non-limiting examples of suitable nanoparticles include, but are not limited to, nanoparticles comprising at least one element from Group IIA, IVA, IIB, IVB, VB, VIIIB, and IIIA. In some embodiments, suitable nanoparticles comprise metal oxides of at least one element from Group IVB, VIIIB, and IIIA. For example, suitable nanoparticles comprise metal oxides of aluminium, titanium, zirconium, iron, tantalum, zinc and mixed metal oxides including metal oxides comprising barium and titanium and strontium and titanium. In some embodiments, suitable nanoparticles include TiO₂, Al₂O₃, ZrO₂, BaTiO₃, Ta₂O₅, Fe₂O₃, ZnO₂, SrTiO₃ nanoparticles and combinations of such nanoparticles including, but not limited to, TiO₂ nanoparticles in combination with Fe₂O₃ nanoparticles. Suitable nanoparticles also include fumed nanoparticulate oxides such as fumed Al₂O₃. Suitable nanoparticles also include nanoparticles comprising at least one element from Group IVA. Examples of such nanoparticles include SiO₂ and combinations of such nanoparticles with metal oxides (e.g., Fe₂O₃) and mixed metal oxides. Still other suitable nanoparticles include nanoparticles comprising metal sulphides, including, but not limited to, ZnS.

In some embodiments, the incorporation of nanoparticles into the compositions described herein provides solid compositions (e.g., films) having an ultra-high refractive index before and/or after curing. As used herein, the term “ultra-high refractive index” refers to refractive indices greater than 1.58, e.g., greater than 1.65, greater than 1.75; from about 1.6 to about 2.5; from about 1.75 to about 2; from about 1.65 to about 2; from about 1.6 to about 1.8, from about 1.61 to about 1.75 or from about 1.62 to about 1.67.

In some embodiments, the amount of nanoparticles present in compositions of the present disclosure is an amount sufficient to produce a solid composition having ultra-high refractive index and, at the same time adequately flexible (i.e., not brittle) as determined, e.g., using the Mandrel Test (ASTM D1737).

In some embodiments, compositions of the present disclosure exhibit melt flow behavior. The compositions of the present disclosure can exhibit melt flow behavior at a nanoparticulate filler content of up to about 50 wt. %. In some embodiments, melt flow behavior can be observed at a nanoparticulate filler content of from about 1 wt. % to about 50 wt. %, e.g., from 5 wt. % to about 20 wt. %, about 10 wt. % to about 25 wt. %, from about 5 wt. % to about 25 wt. %, from about 15 wt. % to about 45 wt. % or from about 20 wt. % to about 50 wt. %.

Solid compositions containing organosiloxane block copolymers and nanoparticulate filler may have a storage modulus (G′) at 120° C. ranging from 500 kPa to 1 MPa and a loss modulus (G″) ranging from 500 kPa to 1 MPa.

Solid compositions containing organosiloxane block copolymers and nanoparticulate filler may have a storage modulus (G′) at 200° C. ranging from 100 kPa to 500 kPa and a loss modulus (G″) ranging from 50 kPa to 400 kPa.

iii) Phosphor

The present compositions may include a phosphor. The phosphor is not particularly limited and may include any known in the art. In one embodiment, the phosphor is made from a host material and an activator, such as copper-activated zinc sulfide and silver-activated zinc sulfide. Suitable but non-limiting host materials include oxides, nitrides and oxynitrides, sulfides, selenides, halides or silicates of zinc, cadmium, manganese, aluminum, silicon, or various rare earth metals. Additional suitable phosphors include, but are not limited to, Ce:YAG; Zn₂SiO₄:Mn (Willemite); ZnS:Ag+(Zn,Cd)S:Ag; ZnS:Ag+ZnS:Cu+Y₂O₂S:Eu; ZnO:Zn; KCl; ZnS:Ag,Cl or ZnS:Zn; (KF,MgF₂):Mn; (Zn,Cd)S:Ag or (Zn,Cd)S:Cu; Y₂O₂S:Eu+Fe₂O₃, ZnS:Cu,Al; ZnS:Ag+Co-on-Al₂O₃; (KF,MgF₂):Mn; (Zn,Cd)S:Cu,Cl; ZnS:Cu or ZnS:Cu,Ag; MgF₂:Mn; (Zn,Mg)F₂:Mn; Zn₂SiO₄:Mn,As; ZnS:Ag+(Zn,Cd)S:Cu; Gd₂O₂S:Tb; Y₂O₂S:Tb; Y₃Al₅O₁₂:Ce; Y₂SiO₅:Ce; Y₃Al₅O₁₂:Tb; ZnS:Ag,Al; ZnS:Ag; ZnS:Cu,Al or ZnS:Cu,Au,Al; (Zn,Cd)S:Cu,Cl+(Zn,Cd)S:Ag,Cl; Y₂SiO₅:Tb; Y₂OS:Tb; Y₃(Al,Ga)₅O₁₂: Ce; Y₃ (Al,Ga)₅O₁₂:Tb; InBO₃:Tb; InBO₃:Eu; InBO₃:Tb+InBO₃:Eu; InBO₃: Tb+InBO₃:Eu+ZnS:Ag; (Ba,Eu)Mg₂Al₁₆O₂₇; (Ce,Tb)MgAl₁₁O₁₉; BaMgAl₁₀O₁₇:Eu,Mn; BaMg₂Al₁₆O₂₇:Eu(II); BaMgAl₁₀O₁₇:Eu,Mn; BaMg₂Al₁₆O₂₇:Eu(II),Mn(II); Ce_{0.67}Tb_{0.33}MgAl₁₁O₁₉:Ce,Tb; Zn₂SiO₄:Mn,Sb₂O₃; CaSiO₃:Pb,Mn; CaWO₄ (Scheelite); CaWO₄:Pb; MgWO₄; (Sr,Eu,Ba,Ca)₅(PO₄)₃Cl; Sr₅Cl(PO₄)₃:Eu(II); (Ca,Sr,Ba)₃(PO₄)₂Cl₂:Eu; (Sr,Ca,Ba)₁₀(PO₄)₆Cl₂:Eu; Sr₂P₂O₇: Sn(II); Sr₆P₅BO₂₀:Eu; Ca₅F(PO₄)₃:Sb; (Ba,Ti)₂P₂O₇:Ti; 3Sr₃(PO₄)₂.SrF₂: Sb,Mn; Sr₅F(PO₄)₃:Sb,Mn; Sr₅F(PO₄)₃:Sb,Mn; LaPO₄:Ce,Tb; (La,Ce,Tb)PO₄; (La,Ce,Tb)PO₄:Ce,Tb; Ca₃(PO₄)₂.CaF₂:Ce,Mn; (Ca,Zn,Mg)₃(PO₄)₂: Sn; (Zn,Sr)₃ (PO₄)₂:Mn; (Sr,Mg)₃ (PO₄)₂: Sn; (Sr,Mg)₃ (PO₄)₂: Sn(II); Ca₅F(PO₄)₃:Sb,Mn; Ca₅(F,Cl)(PO₄)₃:Sb,Mn; (Y,Eu)₂O₃; Y₂O₃:Eu(III); Mg₄(F)GeO₆:Mn; Mg₄(F)(Ge,Sn)O₆:Mn; Y(P,V)O₄:Eu; YVO₄:Eu; Y₂O₂S:Eu; 3.5 MgO.0.5 MgF₂.GeO₂:Mn; Mg₅As₂O₁₁:Mn; SrAl₂O₇:Pb; LaMgAl₁₁O₁₉:Ce; LaPO₄:Ce; SrAl₁₂O₁₉:Ce; BaSi₂O₅:Pb; SrFB₂O₃:Eu(II); SrB₄O₇:Eu; Sr₂MgSi₂O₇:Pb; MgGa₂O₄:Mn(II); Gd₂O₂S:Tb; Gd₂O₂S:Eu; Gd₂O₂S:Pr; Gd₂O₂S:Pr,Ce,F; Y₂O₂S:Tb; Y₂O₂S:Eu; Y₂O₂S:Pr; Zn(0.5)Cd(0.4)S:Ag; Zn(0.4)Cd(0.6)S:Ag; CdWO₄; CaWO₄; MgWO₄; Y₂SiO₅:Ce; YAlO₃:Ce; Y₃Al₅O₁₂:Ce; Y₃ (Al,Ga)₅O₁₂:Ce; CdS:In; ZnO:Ga; ZnO:Zn; (Zn,Cd)S:Cu,Al; ZnS:Cu,Al,Au; ZnCdS:Ag,Cu; ZnS:Ag; anthracene, EJ-212, Zn₂SiO₄:Mn; ZnS:Cu; NaI:Tl; CsI:T1; LiF/ZnS:Ag; LiF/ZnSCu,Al,Au, and combinations thereof.

In some embodiments, the present compositions include Al₂O₃ nanoparticles in combination with a Ce:YAG phosphor.

The amount of phosphor added to the present compositions may vary and is not limiting. When present, the phosphor may be added in an amount ranging from about 0.1% to about 95%, e.g., from about 5% to about 80%, from about 1% to about 60%; from about 25% to about 60%; from about 30% to about 60%; from about 40% to about 60%; from about 50% to about 60%; from about 25% to about 50%; from about 25% to about 40%; from about 25% to about 30%; from about 30% to about 40%; from about 30% to about 50%; or from about 40% to about 50%; based on the total weight of the composition.

In some embodiments, the solutions containing organosiloxane block copolymer, nanoparticulate filler, and phosphor (e.g., from which curable films may be cast) may be sufficiently thick, due to the presence of a nanoparticulate filler, so as to promote deagglomeration (i.e., improved dispersion) of the phosphor and prevent settling of the phosphor in the solution. Solid compositions resulting from these solutions, when used in, e.g., LED applications, may result in the formation of phosphor films having improved light output and color over angle relative to phosphor films lacking a nanoparticulate filler.

Some of the embodiments of the present invention relate to optical assemblies and articles comprising the compositions described herein such as those described in PCT/US2012/071011, filed Dec. 20, 2012; PCT/US2013/021707, filed Jan. 16, 2013; and PCT/US2013/025126, filed Feb. 7, 2013, all of which are incorporated by reference as if fully set forth herein. Accordingly, some embodiments of the present invention relate to an LED encapsulant comprising an organosiloxane block copolymer described herein.

Embodiments of the invention described and claimed herein are not to be limited in scope by the specific embodiments herein disclosed, since these embodiments are intended as illustration of several aspects of the disclosure. Any equivalent embodiments are intended to be within the scope of this disclosure. Indeed, various modifications of the embodiments in addition to those shown and described herein will become apparent to those skilled in the art from the foregoing description. Such modifications are also intended to fall within the scope of the appended claims.

The invention has been described broadly and generically herein. Each of the narrower species and subgeneric groupings falling within the generic disclosure also form part of the invention. This includes the generic description of the invention with a proviso or negative limitation removing any subject matter from the genus, regardless of whether or not the excised material is specifically recited herein. In addition, where features or aspects of the invention are described in terms of Markush groups, those skilled in the art will recognize that the invention is also thereby described in terms of any individual member or subgroup of members of the Markush group.

As used herein and in the appended claims, the singular forms “a,” “an,” and “the” include plural reference unless the context clearly dictates otherwise. Thus, for example, a reference to “a reactor” includes a plurality of reactors, such as in a series of reactors. In this document, the term “or” is used to refer to a nonexclusive or, such that “A or B” includes “A but not B,” “B but not A,” and “A and B,” unless otherwise indicated.

Values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “about 0.1% to about 5%” or “about 0.1% to 5%” should be interpreted to include not just about 0.1% to about 5%, but also the individual values (e.g., 1%, 2%, 3%, and 4%) and the sub-ranges (e.g., 0.1% to 0.5%, 1.1% to 2.2%, 3.3% to 4.4%) within the indicated range. The statement “about X to Y” has the same meaning as “about X to about Y,” unless indicated otherwise. Likewise, the statement “about X, Y, or about Z” has the same meaning as “about X, about Y, or about Z,” unless indicated otherwise.

The term “about” as used herein can allow for a degree of variability in a value or range, for example, within 10%, within 5%, or within 1% of a stated value or of a stated limit of a range.

All publications, including non-patent literature (e.g., scientific journal articles), patent application publications, and patents mentioned in this specification are incorporated by reference as if each were specifically and individually indicated to be incorporated by reference.

The Abstract is provided to allow the reader to quickly ascertain the nature of the technical disclosure. It is submitted with the understanding that it will not be used to interpret or limit the scope or meaning of the claims.

### EXAMPLES

The following examples are included to demonstrate specific embodiments of the invention. However, those of skill in the art should, in light of the present disclosure, appreciate that many changes can be made in the specific embodiments which are disclosed and still obtain a like or similar result without departing from the spirit and scope of the invention. All percentages are in wt %. All measurements were conducted at 23° C. unless indicated otherwise.

### Example 1

### (PhMeSiO_{2/2})_{0.52}(PhSiO_{3/2})_{0.42} (45 wt % Phenyl-T)

A 12 L 3-neck round bottom flask was loaded with Dow Corning 217 Flake (1514.5 g, 11.09 moles Si) and toluene (Fisher Scientific, 1247.0 g). The flask was equipped with a thermometer, Teflon stir paddle, and a Dean Stark apparatus attached to a water-cooled condenser. A nitrogen blanket was applied; the Dean Stark apparatus was prefilled with toluene; and an oil bath was used for heating. The reaction mixture was heated at reflux for 30 minutes. After cooling the reaction mixture to 108° C., a solution of diacetoxy terminated PhMe siloxane in toluene was added quickly.

The diacetoxy terminated PhMe siloxane was prepared by adding a 50/50 wt. % MTA/ETA (methyltriacetoxysilane/ethyltriacetoxysilane) (47.29 g, 0.2080 moles Si) mixture to a solution of 140 dp silanol terminated PhMe siloxane (1851.1 g, 13.57 moles Si) dissolved in toluene (65% solids). The solution was mixed for 2 hours at room temperature under a nitrogen atmosphere.

After the diacetoxy terminated PhMe siloxane was added, the reaction mixture was heated at reflux for 2 hours. At this stage 50/50 wt % MTA/ETA (264.61 g, 1.164 moles Si) was added at 108° C. The reaction mixture was heated at reflux for an additional 1 hour. The reaction mixture was cooled to 90° C. and then deionized (DI) water (393 mL) was added. The temperature was increased to reflux and the water (488.7 g) was removed by azeotropic distillation. The reaction mixture was cooled again to 90° C. and more DI water (393 mL) was added. The reaction mixture was once again heated up to reflux and the water (468.3 g) was removed. Some toluene (813.3 g) was then removed by distillation to increase the solids content. The material was cooled to room temperature and then pressure filtered through a 5.0 μm filter. Films (about 0.8 mm thick) cast from the toluene solution (made by pouring the solution in a chase and evaporating the solvent) were optically clear.

### Example 2

### 1 mm Thick Resin Linear/Nanoparticle Films

The resin-linear toluene solution (˜70% solids) made according to Example 1 was mixed with Aeroxide Alu C (Evonik) using a planetary mixer. A catalyst, namely Al(AcAc)₃ (200 ppm Al), was added. After planetary mixing, the solution was diluted to about 60% solids and a sonic horn mixer was used for 1 minute at 60 W power. Mixtures of filler/resin-linear/toluene were poured into a cavity to prepare an approximately 1 mm thick sample. See Table 1.

TABLE 1

| | Aeroxide | Vol % vs. Total | |
|---|---|---|---|
| Sample | Alu C | Solids | Appearance |
| 1 | None | 0 | Optically clear |
| 2 | Yes | 4 | Translucent |
| 3 | Yes | 6 | Translucent |
| 4 | Yes | 9 | Translucent |
| 5 | Yes | 15 | Slightly Cloudy |
| 6 | Yes | 28 | Cloudy |

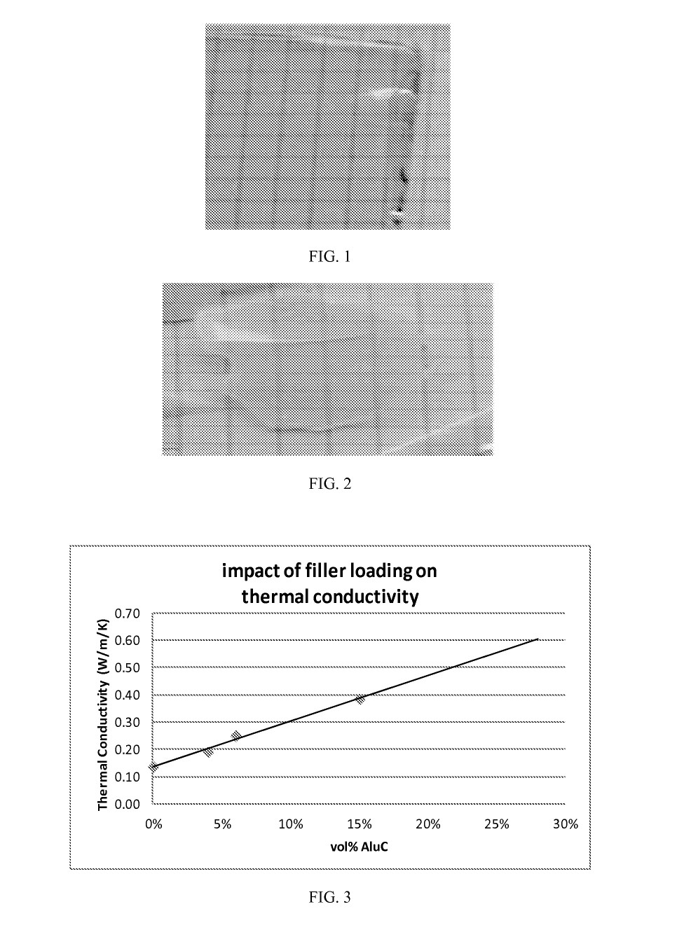

FIGS. 1 and 2 show the appearance of the Sample 1 and Sample 5 films, respectively. FIG. 3 is a plot of vol % Alu C vs. thermal conductivity (W/m/K) and shows that, at least for the vol % Alu C range tested, the thermal conductivity was linear with regard to the vol % Alu C.

### Example 3

### Thin Resin Linear/Nanoparticle Films

The resin-linear toluene solution (˜70% solids) made according to Example 1 was mixed with Aeroxide TiO₂ 545 S (Evonik), Aeroxide TiO₂ 1580 S (Evonik), Aeroxide TiO₂PF2 (Evonik) or BaTiO₃ (Inframat) using a planetary mixer and, in some instances, in combination with an ultra-sonic mixer, to provide samples loaded with 15 vol. % nanoparticles. Compositions using Al₂O₃ and Fe₂O₃/SiO₂ may be made in a similar fashion. A catalyst, namely Al(AcAc)₃ (200 ppm Al), was added. The 70% solids solutions containing the nanoparticles were cast using a 4 mil draw down bar to obtain a thin film. The resulting observations are in the below table.

Oscillatory strain rheology was run to determine the extent of flow after addition of the nanoparticles. The data in Table 2 shows that the nanoparticle-containing samples still allow for partially transparent film formation. Also, although G′ increases and tan δ decreases when 15 vol. % nanoparticles are present, which is an indication of reduced melt flow, a sufficient melt flow is retained thus making these solid film materials viable candidates for protection of electronic devices through melt processing schemes.

TABLE 2

| | | | | G′ at | |
|---|---|---|---|---|---|
| | | Thickness, | | 140° C. | Tan δ at |
| Sample | Nanoparticles | μm | Appearance | kPa | 140° C. |
| 7 | Aeroxide | 80 | Partially | 111 | 0.70 |
| | TiO₂ 545S | | translucent | | |
| 8 | Aeroxide | 50 | Translucent | 760 | 0.62 |
| | TiO₂ 1580S | | | | |
| 9 | Aeroxide | 57 | Translucent | 156 | 0.75 |
| | TiO₂ PF2 | | | | |
| 10 | BaTiO₃ | 56 | Partially | 9.3 | 1.45 |
| | | | translucent | | |
| 11 | None | 60 | Transparent | 2.0 | 1.76 |

### Example 4

### 45 wt. % Naphthyl-T-55 wt. % 45 dp PhMe siloxane

A 50 mL 1-neck round bottom flask was loaded with 2.4 g of a naphthyl-T hydrolyzate resin flake (prepared by hydrolyzing naphthyl trimethoxysilane used as purchased from Gelest) and toluene (Fisher Scientific, 5.6 g). The flask was equipped with a magnetic stir bar and a Dean Stark apparatus attached to a water-cooled condenser. A nitrogen blanket was applied, Dean Stark was prefilled with toluene, and an oil bath was used for heating. The reaction mixture was heated at reflux for 30 min. After cooling the reaction mixture to 108° C., a solution of diacetoxy terminated PhMe siloxane was added quickly. The diacetoxy terminated PhMe siloxane was prepared by adding a 50/50 wt % MTA/ETA (0.065 g, 0.00028 moles Si) mixture to a solution of 45 dp silanol terminated PhMe siloxane (2.93 g, 0.0215 moles Si) dissolved in toluene (6.84 g). The solution was mixed for 2 hours at room temperature under a nitrogen atmosphere. After the diacetoxy terminated PhMe siloxane was added, the reaction mixture was heated at reflux for 2 hours. At this point the following process was repeated three times: 50/50 wt % MTA/ETA (0.21 g, 0.000908 moles Si) was added at 108° C. The reaction mixture was heated at reflux for 1 hour. It was cooled to 90° C. and then DI water (2 mL) was added. Temperature was increased to reflux and the water was removed by azeotropic distillation. Cast sheets were optically clear.

### Example 5

### Film Containing ZrO₂

A resin-linear toluene solution (˜70% solids) made according to Example 4 was diluted with methyl ethyl ketone. ZrO₂ (OZ-530K; Nissan Chemical; primary particle size=10 nm) was added to the solution to give a 33 wt. % dispersion. Films were prepared by the solvent casting method using 1.2 mm glass plate as spacers such that once the solvent had evaporated, films having a thickness of no more than 0.4 mm were obtained. Cast films were allowed to stand at room temperature overnight, heated at 50° C. for 3-4 hours and heated at 50° C. for 2 hours in vacuum oven. The resultant films, which were translucent in appearance, were cured at 170° C. for 2 hour in the absence of a curing catalyst or in the presence of 50 ppm of DBU or 200 ppm of Al(AcAc)₃. Though the films were brittle after curing, the refractive index of the films was 1.625 at 644 nm.

It has been found that the brittleness of the film can be alleviated by reducing the resin content of the resin-linear organosiloxane block copolymer. Thus, for example, resin-linear organosiloxane block copolymers containing, e.g., 35 wt. % Naphthyl-T content and 65 wt. % 56 dp PhMe siloxane content and up to 50 wt. % ZrO₂ can give flexible films before and after curing.

### Example 6

### Film Containing BaTiO₃

Toluene was partially removed in vacuo from toluene dispersions containing BaTiO₃ nanoparticles (Toda Kogyo Co., Ltd. with primary particle size of 35 nm and secondary particle size of 1 micrometer). The dispersions were prepared using an ultrasonic homogenizer (Nippon Seki's US-300T) while heating (<80° C.) in vacuo so that the solid content was approximately 70%. The curing catalysts like DBU (50 or 100 ppm), Al(AcAc)₃ (200 ppm) or Zn octoate (Zn: 1000-2000 ppm) was added, as necessary. The resultant dispersion was casted and the casted films were allowed to stand at room temp. overnight, heated at 50° C. for 3-4 hrs and heated at 50° C. for 2 hours in vacuum oven. The resultant films were cured at 170-190° C. for 2 hours in the absence of a curing catalyst or in the presence of the curing catalyst like DBU, Al(AcAc)₃ or Zn octoate.

While not wishing to be bound by any particular theory, over the course of testing various BaTiO₃ nanoparticle-containing resin linear compositions (see Table 3 below), it is possible that the resin linear organosiloxane block copolymer itself could act as both a dispersant and a matrix polymer. It is possible that silanol groups on the resin linear organosiloxane block copolymer interact (e.g., via hydrogen bonding) with OH groups on BaTiO₃ particles such that the resin linear organosiloxane block copolymer helps disperse the BaTiO₃ nanoparticles.

TABLE 3

| | Sample | | | | | |
|---|---|---|---|---|---|---|
| | 12 | 13 | 14 | 15 | 16 | 17 |
| BaTiO₃¹ | 4.5 g | 4.5 g | 4.5 g | 2.73 g | 4.5 g | 4.5 g |
| Resin Linear | Ph-T 35 wt. | Ph-T 40 wt. | Ph-T 45 wt. | Ph-T 45 wt. | Np-T 35 wt. | Np-T 45 wt. |
| | %/PhMe 65 wt. % | %/PhMe 60 wt. % | %/PhMe 55 wt. % | %/PhMe 55 wt. % | %/PhMe 65 wt. % | %/PhMe 55 wt. % |
| | 4.5 g | 4.5 g | 4.5 g | 6.3 g | 4.5 g | 4.5 g |
| Conversion(%)² | 90.8 | 91 | 91.9 | 92.8 | 94 | 92.9 |
| BaTiO₃ cont. | 47.6 | 47.6 | 47.9 | 28.7 | 48.5 | 48.2 |
| (wt. %)² | | | | | | |
| (resin + BaTiO₃) | 65.9 | 68.6 | 71.3 | 60.8 | 66.5 | 71.5 |
| cont. (wt %) | | | | | | |
| (resin + BaTiO₃) | 43.5 | 47.9 | 52.3 | 48.5 | 43.8 | 52.4 |
| cont. (vol %) | | | | | | |
| Cumulant | 127.2 | 123.8 | 113.8 | 117.7 | 106.8 | 110.8 |
| Particle size d | | | | | | |
| (nm) | | | | | | |
| Polydispersity P. | 0.108 | 0.108 | 0.125 | 0.122 | 0.081 | 0.101 |
| I. | | | | | | |
| RI before curing | 1.64933 Flexible | 1.65804 Flexible | 1.64472 Crack | 1.59228 Part. | 1.68084 Flexible | 1.67716 Flexible |
| | | | | crack | | |
| RI after 190° C., 2 | 1.65515 Flexible | 1.66363 Flexible | 1.66056 Brittle | 1.60196 Flexible | 1.68476 Flexible | 1.68554 |
| hours | | | | | | Slight brittle |

¹150° C., 1 hour
²Calculated from the weight of recovered BaTiO₃ large particle filtration.

Table 3 shows various BaTiO₃ nanoparticle-containing resin linear compositions where the resin portion varied between Ph-T and Np-T; the resin content varied between 35 wt. % to 45 wt. %; the BaTiO₃ content varied between 30 wt. % and 50 wt. %; and the cumulant particle size of BaTiO₃ measured by light scattering method varied between 107 nm and 127 nm.

The brittleness of the composition films depended upon both resin content and BaTiO₃ content and a critical point appears to occur at 50 vol. % of resin plus BaTiO₃ content. When this content was larger than 50 vol. %, the composition film was generally brittle and sometimes cracked during casting. On the other hand, when the resin content was less than 50 vol. %, the composition films were generally flexible.

1. A curable composition comprising:
i) an organosiloxane block copolymer comprising:
40 to 90 mole percent disiloxy units of the formula [R¹₂SiO_{2/2}],
10 to 60 mole percent trisiloxy units of the formula [R²SiO_{3/2}];
wherein:
each R¹, at each occurrence, is independently a C₁ to C₃₀ hydrocarbyl,
each R², at each occurrence, is independently a C₁ to C₂₀ hydrocarbyl;
wherein:
the disiloxy units [R¹₂SiO_{2/2}] are arranged in linear blocks having an average of from 10 to 400 disiloxy units [R¹₂SiO_{2/2}] per linear block,
the trisiloxy units [R²SiO_{3/2}] are arranged in non-linear blocks having a molecular weight of at least 500 g/mole, and at least 30% of the non-linear blocks are crosslinked with each other, each linear block is linked to at least one non-linear block; and
ii) a nanoparticulate filler.

2. The curable composition of claim 1, wherein the composition exhibits melt flow behavior.

3. The curable composition of claim 1, wherein the composition exhibits melt flow behavior at a nanoparticulate filler content of up to about 50 wt. %.

4. The curable composition of claim 1, further comprising a solvent and/or a phosphor.

5. The curable composition of claim 4, wherein the solvent is a polar solvent.

6. The curable composition of claim 5, wherein the polar solvent comprises tetrahydrofuran.

7. The curable composition of claim 1, wherein the nanoparticulate filler is present in an amount of from about 1% to about 60% based on the total weight of the composition.

8. The curable composition of claim 1, wherein R² is phenyl.

9. The curable composition of claim 1, wherein R² is naphthyl.

10. The curable composition of claim 1, wherein R¹ is methyl or phenyl.

11. The curable composition of claim 1, wherein the disiloxy units have the formula [CH₃)(C₆H₅)SiO_{2/2}].

12. The curable composition of claim 1, wherein the disiloxy units have the formula [CH₃)₂SiO_{2/2}].

13. A solid film composition comprising the curable composition of claim 1.

14. The solid film composition of claim 13, wherein the solid composition has an optical transmittance of at least 95%.

15. The solid film composition of claim 13, wherein the solid composition has an ultra-high refractive index.

16. The cured product of the composition of claim 1.

17. The cured product of claim 16, wherein the cured product has an ultra-high refractive index.

18. The cured product of claim 16, wherein the cured product is flexible.

19. The cured product of claim 18, wherein the cured product comprises less than 50 vol. % nanoparticulate filler.

20. An LED encapsulant comprising the compositions of claim 1.
